(19) United States
(12) Patent Application Publication
(10) Pub. No.: US 2013/0000556 A1
(43) Pub. Date: Jan. 3, 2013

(54) APPARATUS FOR THE DEPOSITION OF SEMICONDUCTOR MATERIAL ON A GLASS SHEET

(76) Inventor: Marco Ronchi, Brescia (IT)

(21) Appl. No.: 13/634,339

(22) PCT Filed: Feb. 24, 2011
(86) PCT No.: PCT/EP11/00897

§ 371 Date: Sep. 12, 2012

(30) Foreign Application Priority Data
Mar. 15, 2010 (IT) MI2010A000416

(51) Int. Cl. H01L 21/203

(52) U.S. Cl. 118/719; 118/729; 118/720; 118/725; 118/724

(57) ABSTRACT

An apparatus for the deposition of semiconductor material on a glass sheet, including at least one vacuum chamber which includes a means for deposition of a semiconductor material on one or more glass sheets and a means for conveying the glass sheets inside the vacuum chamber; the conveyance means forms a continuous plane with the surface of the panels that is subjected to the deposition of conducting material.

The present invention relates to an apparatus for the deposition of semiconductor material on a glass sheet.

More particularly, the present invention relates to an apparatus for depositing thin films of two semiconductors on glass sheets of various dimensions and shapes, more typically rectangular, for manufacturing photovoltaic panels. The two semiconductors can be cadmium sulfide and cadmium telluride.

As is known, photovoltaic panels are generally manufactured by heating glass sheets inside a chamber in which the semiconductor material is diffused and deposits on one side of the sheets in the form of a thin film.

Various systems for the continuous production of photovoltaic panels have been proposed in which the glass panels are conveyed inside an elongated chamber.

EP-0640247 discloses a method and an apparatus for manufacturing photovoltaic panels by making glass panels slide in a horizontal position on a roller conveyor inside a heated chamber in which the semiconductor material is deposited on the upper face of the panels by evaporation.

U.S. Pat. No. 6,875,468 discloses a method and a device for manufacturing a photovoltaic panel in which the surface of the panel to be coated is arranged at an angle with respect to the vertical and the gas strikes the surface so that it flows along it, starting from the base.

US2008/0187766 discloses a system in which the glass sheets, suspended in a vertical position, are conveyed inside a vacuum chamber through a heating station, a deposition station and a cooling station.

U.S. Pat. No. 5,170,714 discloses a transportation system for a vacuum processing apparatus comprising a magnetically floating type linear motor.

The aim of the present invention is to provide an apparatus that is improved with respect to the systems of the prior art for the continuous manufacture of photovoltaic panels.

Within the scope of this aim, an object of the invention is to provide an apparatus with a system for conveying the glass sheets that allows to support the glass sheet at temperatures even above 600° C. without deformations and with reduced risk of breakage, differently from traditional roller conveyance systems.

Another object of the invention is to provide an apparatus in which it is possible to prevent the deposited material from reaching and dirtying the side of the sheet that will be exposed to the sun of the photovoltaic panel, allowing to avoid a subsequent step of cleaning the plate.

Another object is to provide an apparatus with a conveyance system that allows to make the glass sheets or plates pass in the deposition stations in an adjacent position, at a minimal distance from each other, so as to minimize turbulence, edge effects and consequent irregularities in the distribution of the film and waste of material.

Another object of the present invention is to provide an apparatus which, thanks to its particular constructive characteristics, is capable of giving the greatest assurances of reliability and safety in use.

This aim and these and other objects that will become better apparent hereinafter are achieved by an apparatus for the deposition of semiconductor material on a glass sheet, comprising at least one vacuum chamber which comprises a means for deposition of a semiconductor material on one or more glass sheets and a means for the conveyance of said glass sheets inside said vacuum chamber; characterized in that said conveyance means forms a continuous plane with the surface of said sheets that is subjected to the deposition of conducting material.

Further characteristics and advantages will become better apparent from the description of preferred but not exclusive embodiments of the invention, illustrated by way of non-limiting example in the accompanying drawings, wherein:

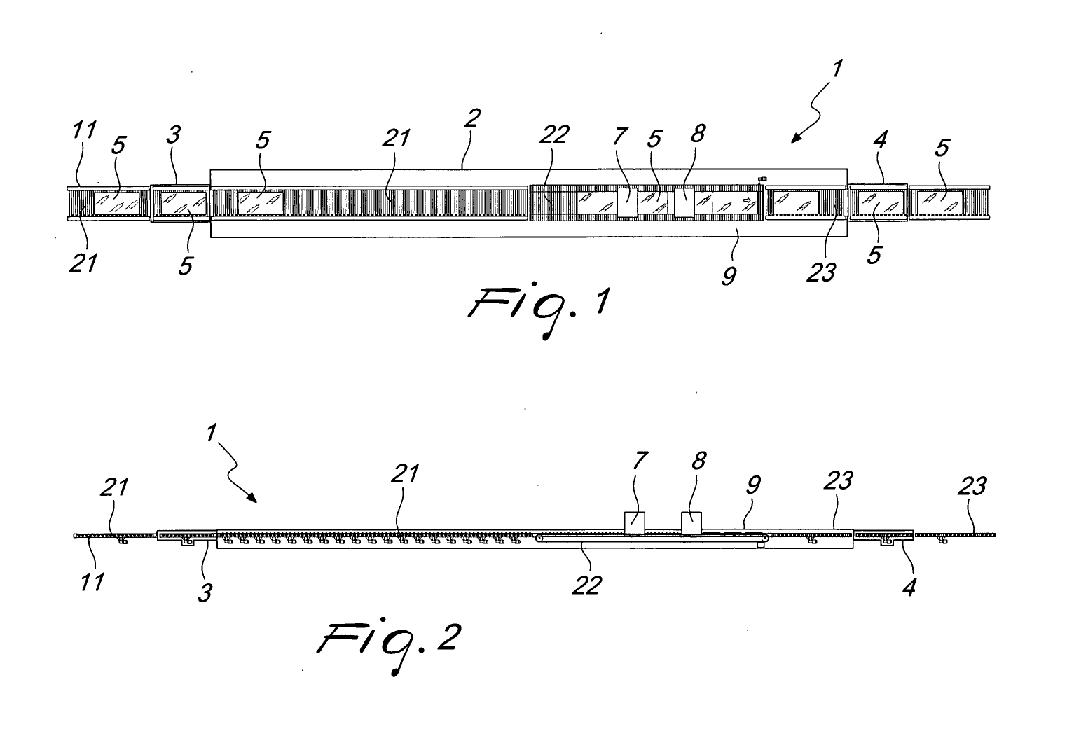

FIG. 1 is a longitudinal section schematic plan view of the apparatus according to the invention;

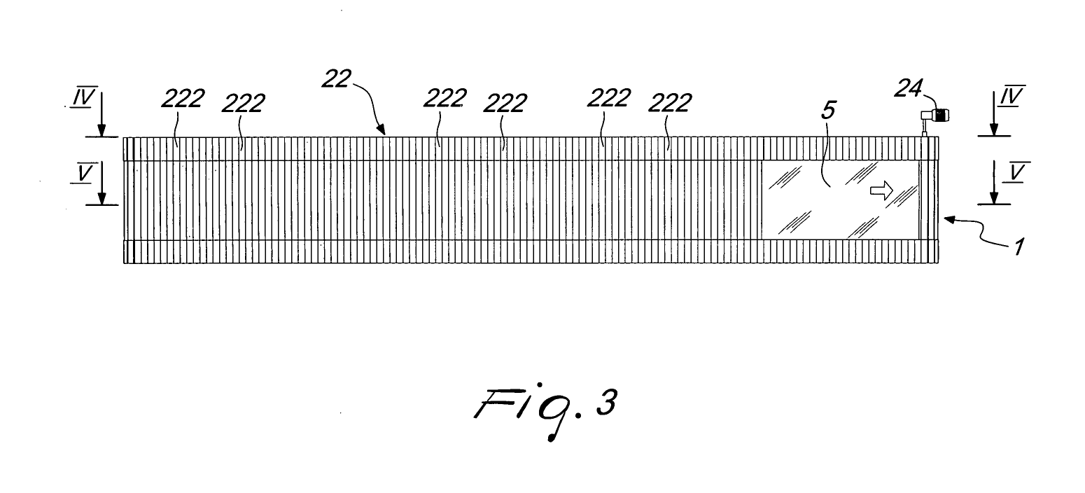

FIG. 2 is a section side view of the apparatus;

FIG. 3 is a longitudinal section plan view of the deposition region;

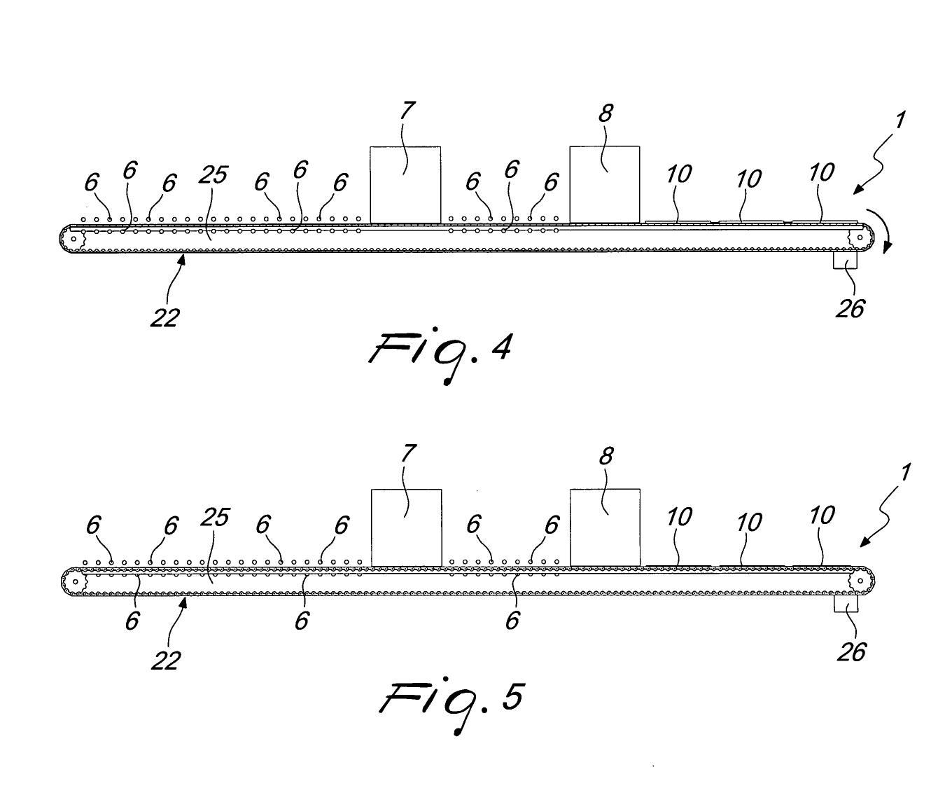

FIG. 4 is a section side view, taken along the sectional plane IV-IV of FIG. 3;

FIG. 5 is a section side view, taken along the sectional plane V-V of FIG. 3;

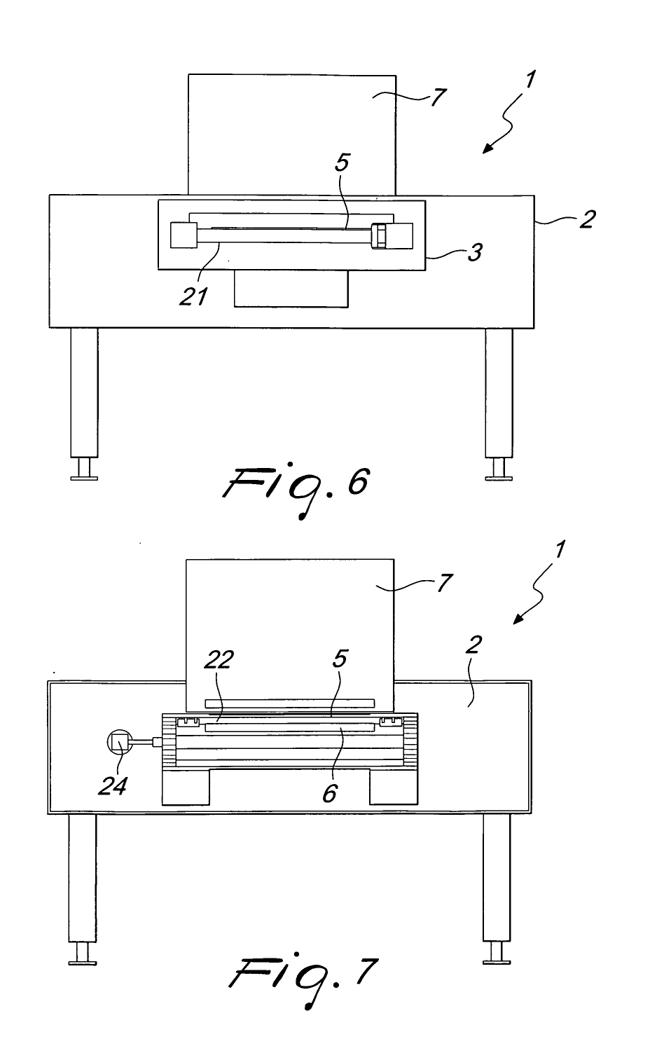

FIG. 6 is a front view of the apparatus;

FIG. 7 is a cross section front view of the apparatus;

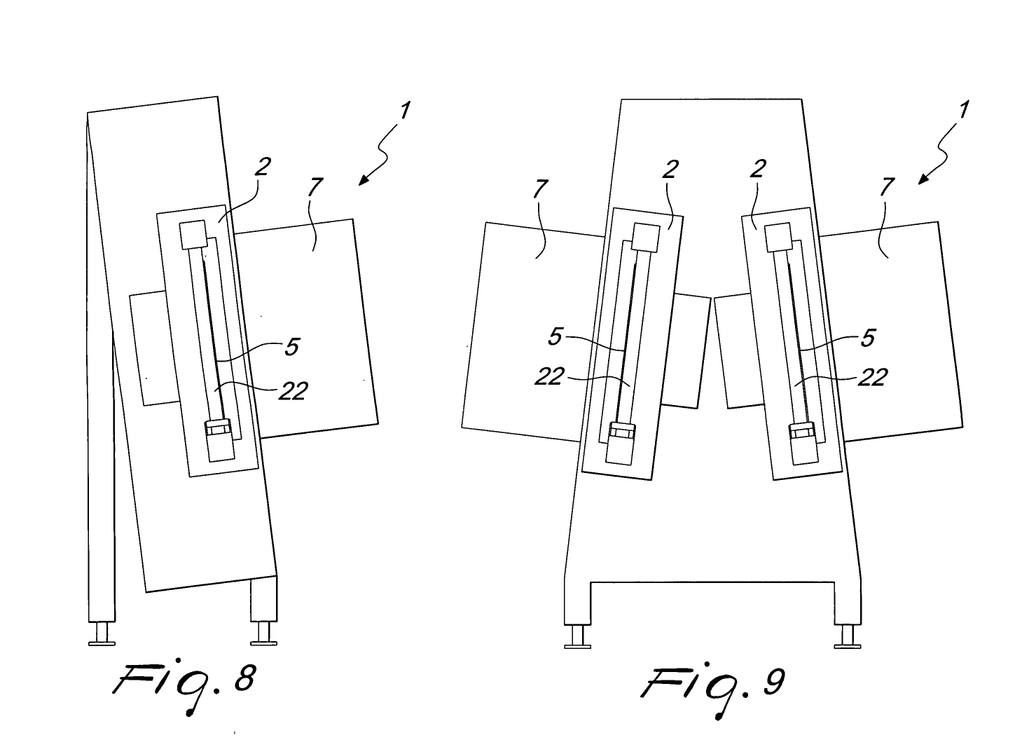

FIG. 8 is a cross section front view of the apparatus according to another aspect of the invention;

FIG. 9 is a cross section front view of the apparatus according to a further aspect of the invention;

FIG. 10 is a longitudinal section schematic plan view of a further embodiment of the apparatus according to the invention;

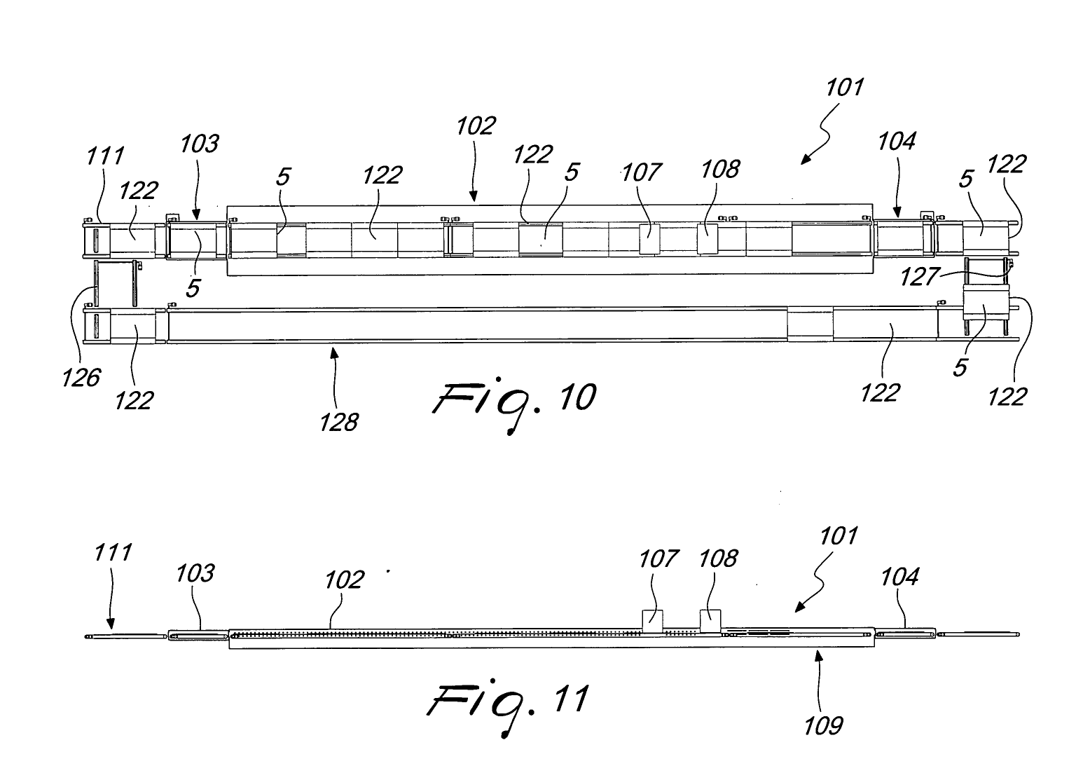

FIG. 11 is a section side view of the apparatus of the preceding figure;

FIG. 12 is a front view of the apparatus of the preceding figure;

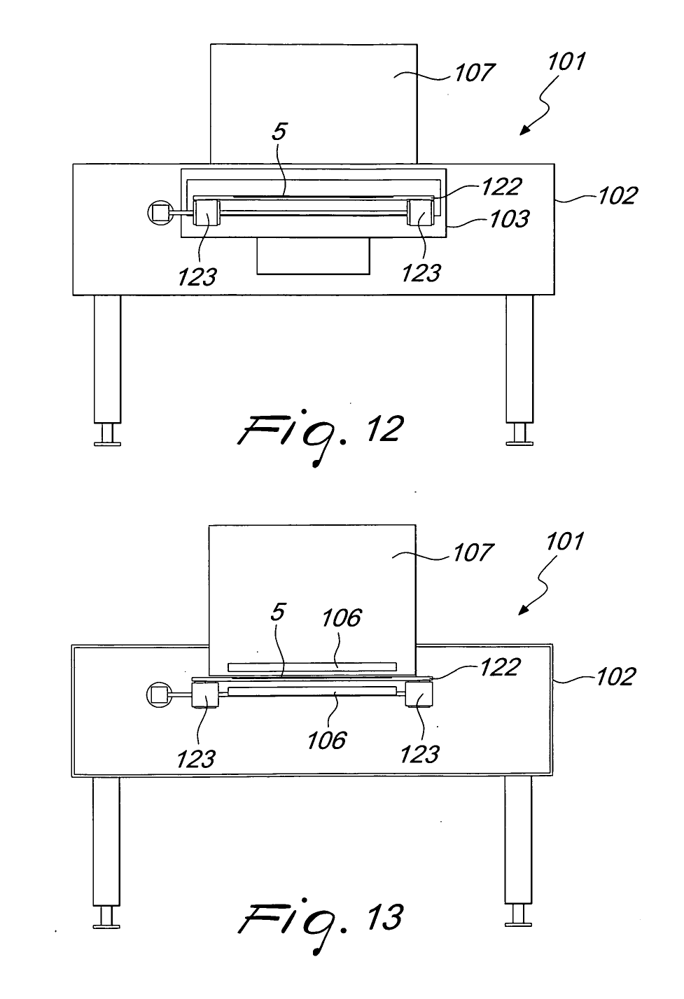

FIG. 13 is a cross section front view of the apparatus of the preceding figure;

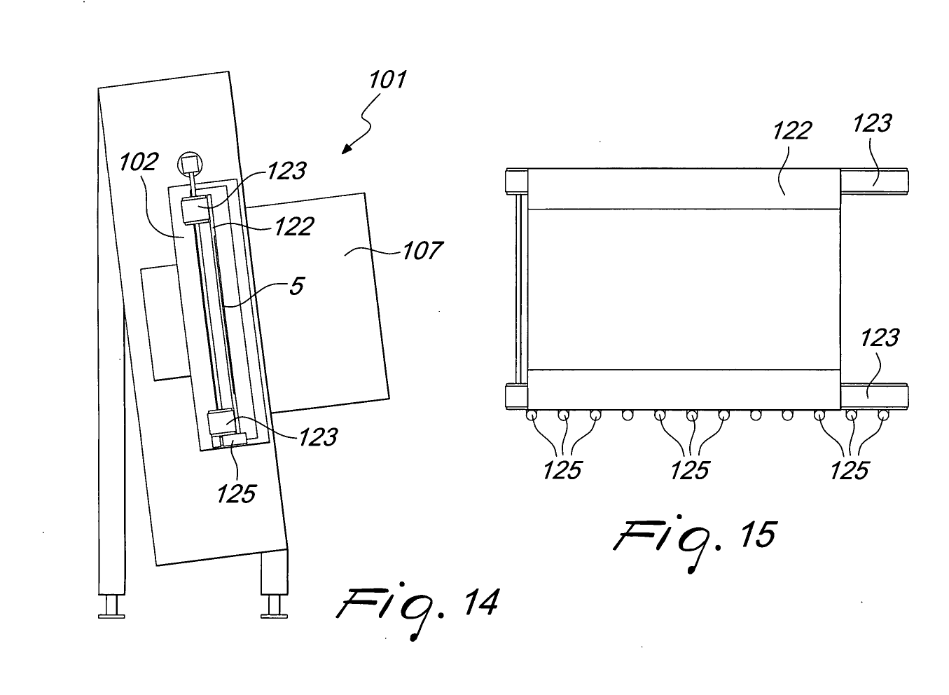

FIG. 14 is a cross section front view of the apparatus according to a further aspect of the invention;

FIG. 15 is a side view of the portion of apparatus of the preceding figure;

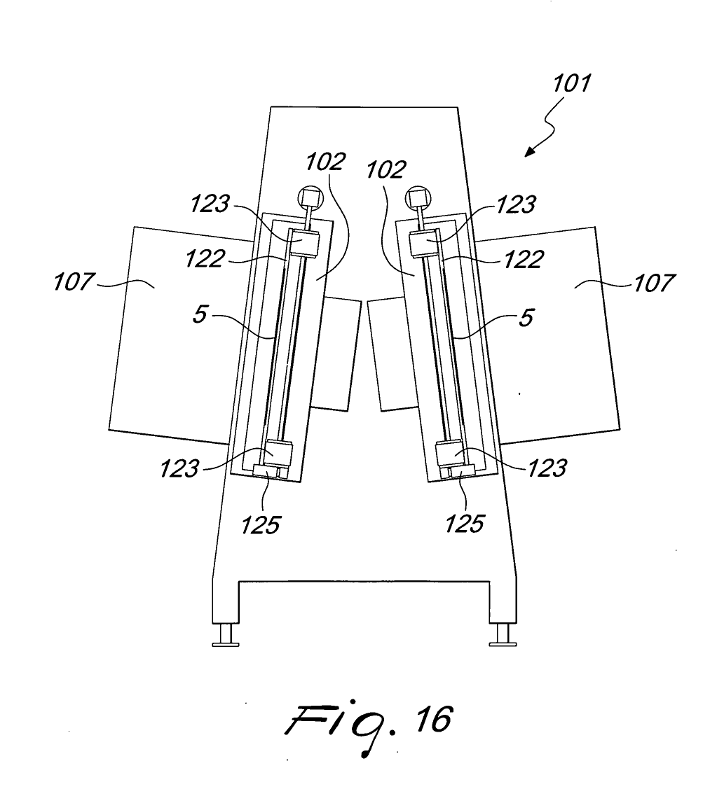

FIG. 16 is a cross section front view of the apparatus according to a further aspect of the invention;

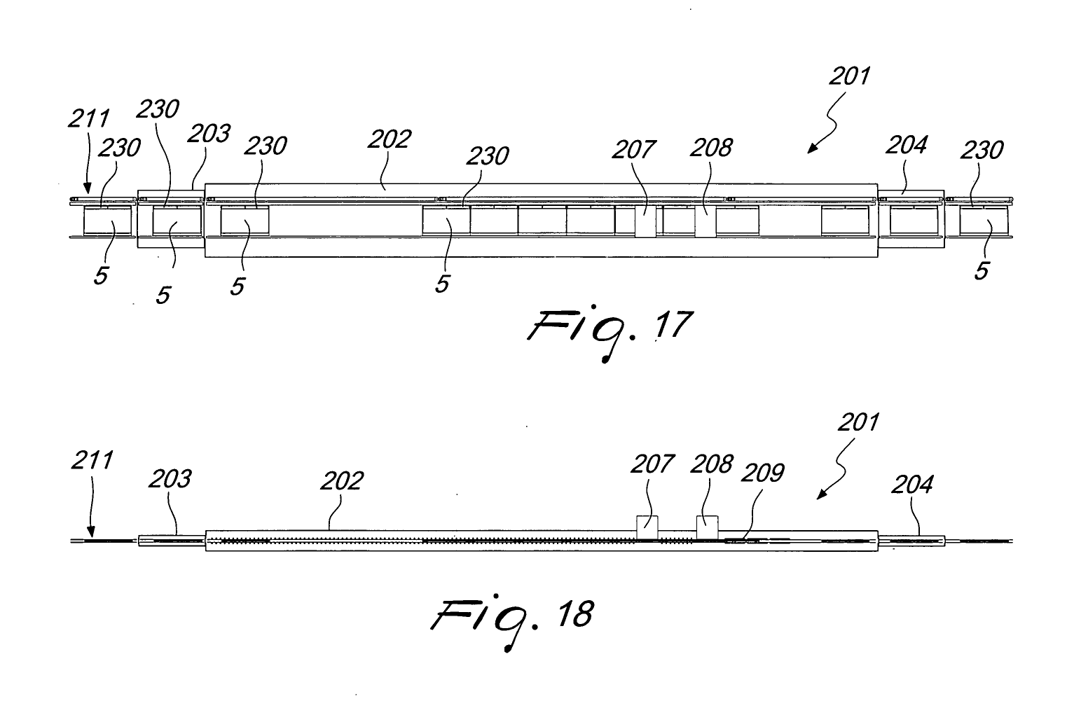

FIG. 17 is a schematic longitudinal section plan view of a further embodiment of the apparatus according to the invention;

FIG. 18 is a section side view of the apparatus of the preceding figure;

FIG. 19 is a front view of the apparatus of the preceding figure;

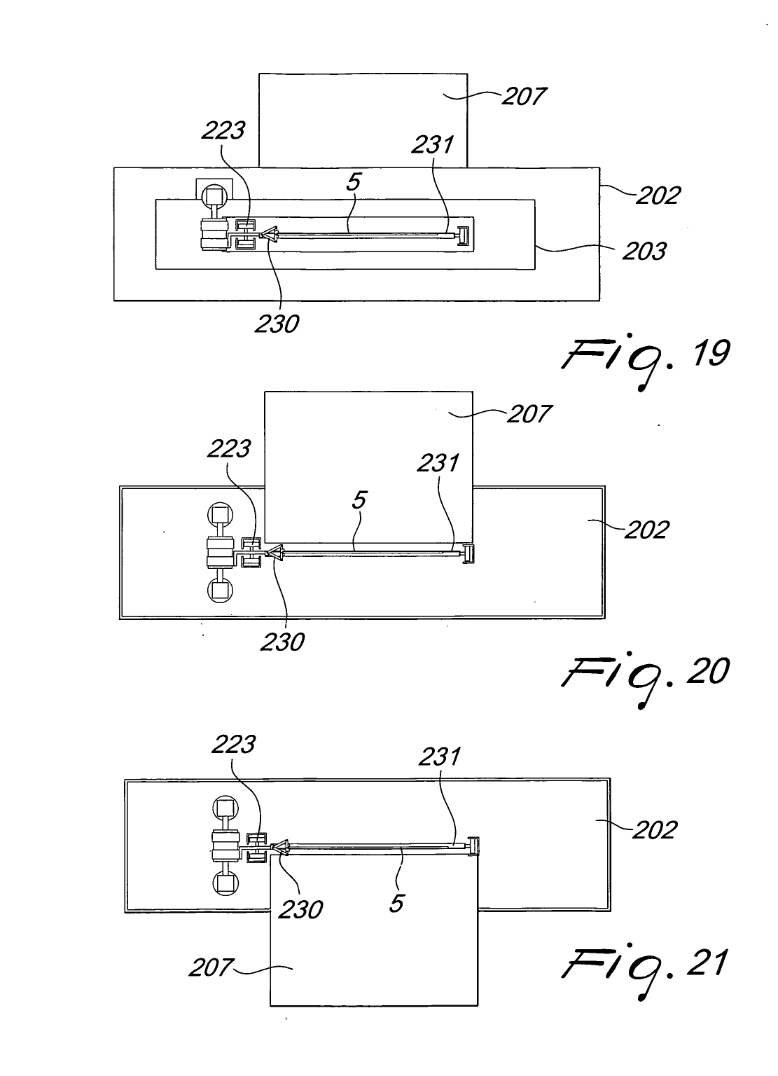

FIG. 20 is a cross section front view of the apparatus of the preceding figure;

FIG. 21 is a cross section front view of the apparatus according to a further aspect of the invention;

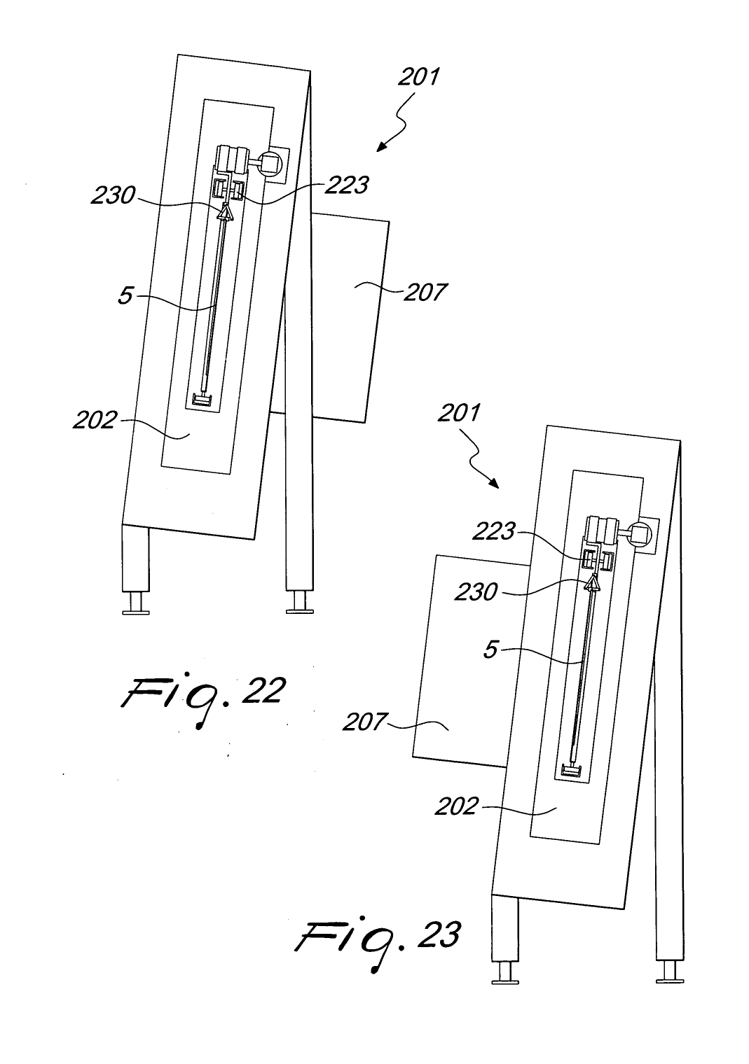

FIG. 22 is a cross section front view of the apparatus according to a further aspect of the invention;

FIG. 23 is a cross section front view of the apparatus according to a further aspect of the invention;

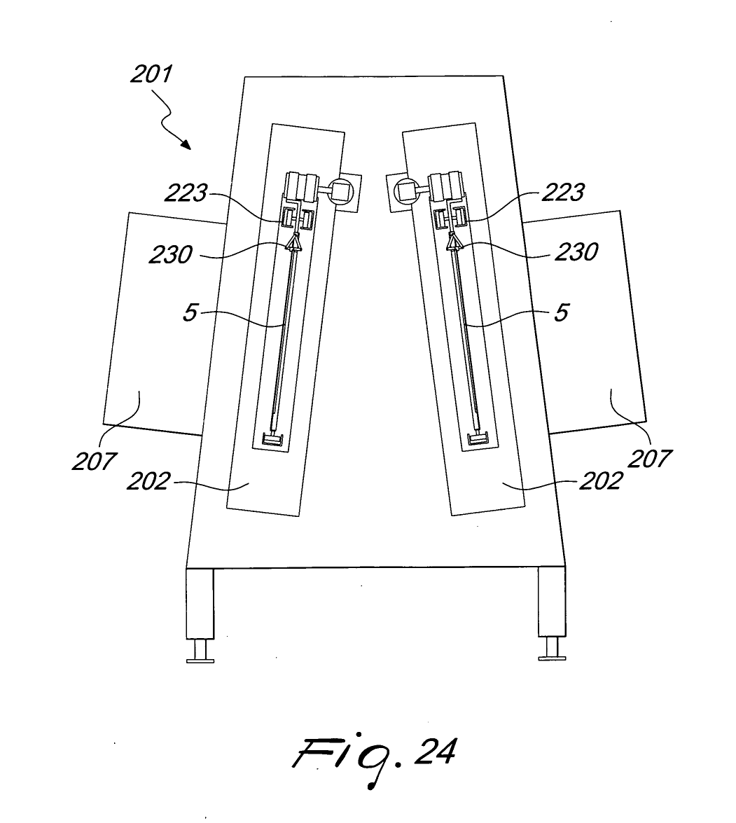

FIG. 24 is a cross section front view of the apparatus according to a further aspect of the invention.

With reference to the cited figures, the apparatus according to the invention, generally designated by the reference numeral 1, comprises a vacuum chamber 2, an entry load lock 3 and an exit load lock 4.

The vacuum chamber 2 is provided with vacuum pumps capable of vacuum levels above 20 torr.

The entry load lock 3 has the minimum cross-section and volume indispensable in order to accommodate the glass sheet 5, so as to minimize emptying time.

The exit load lock 4 accommodates a subsystem which provides the surface tensioning in nitrogen of the glass sheet.

The orientation of the glass sheets through the apparatus can be horizontal or inclined.

The vacuum chamber has a conveyance system which is adapted to move the glass sheet from the entry load lock to the chamber 2, inside the chamber 2, and from the chamber 2 to the exit load lock 4.

The vacuum chamber 2 comprises a series of electric heaters 6 for heating the glass sheet from ambient temperature to the semiconductor deposition temperature, which is comprised between approximately 550° C. and 680° C.

The vacuum chamber 2 has a first station 7, for depositing the first semiconductor by evaporation or sublimation, a second station 8, for depositing the second semiconductor by evaporation or sublimation, and a cooling station 9 provided with absorbers 10.

The heaters 6 are arranged on both faces of the glass sheet, parallel to it, and are controlled by means of independent control systems which allow to manage the level of irradiation in a differentiated manner along the two dimensions of the glass sheet and on the two sides.

The absorbers 10 are arranged on both faces of the glass sheet, parallel to it, and are controlled by means of independent control systems which allow to manage the level of irradiation in a differentiated manner along the two dimensions of the glass and on the two sides.

The vacuum chamber is provided with ports which allow rapid replacement of all the elements: heaters, absorbers, deposition stations, components of the conveyance system.

The mechanical belt conveyance system, shown in FIGS. 1-9, has three sections.

A first section comprises motorized rollers 21, which convey the glass sheet 5 from the loading station 11 to the entry load lock 3, from the entry load lock 3 into the vacuum chamber 2, through the first heaters 6, until it reaches the glass sheets 5 that precede it.

A central section of the conveyance system has a mechanical belt with segments 22, as described better hereinafter, which is adapted to support the glass sheet 5 in the deposition regions 7 and 8.

A third section comprises rollers 23, similar to the first section, where the glass sheet 5 is conveyed to the exit load lock 4, where tensioning occurs.

In the first roller section, each roller or group of rollers 21 has an independent movement system. In this manner each glass sheet 5 may have a different speed with respect to the others and may stop while the others remain in motion. In this manner the glass sheet can proceed from the loading region 11 to the entry load lock 3, stay in the entry load lock 3 for the required time, pass from the entry load lock 3 to the vacuum chamber 2, continue through the first heaters 6 at a higher speed than the ones that precede it, reach the glass sheet 5 that precedes it and queue behind it at a preset distance, which can even be nil, be heated to a temperature of approximately 550° C., such as not to cause deformations of the glass sheet on the rollers even in case of a temporary stop, and proceed at the same speed as the glass sheets that precede it on the mechanical belt 22.

In the embodiment with an inclined roller bed, idle rollers support the glass sheet along the profile, preventing from sliding and ensuring its alignment.

In the central section, the conveyance system is constituted by a mechanical belt 22 constituted by segments 222 made of an adequate material, for example graphite or ceramics.

The mechanical belt 22 presents a flat surface to the glass sheets 5. The flat surface is constituted by the individual segments 222 arranged side by side at a distance of a few tenths of a millimeter, shaped so as to accommodate the entire thickness of the glass sheet and generating a continuous flat surface which is also extended beyond the glass sheet 5.

The flat surface of the mechanical belt conveyor offers several advantages.

First of all, the flat surface of the conveyor allows to support the glass sheet 5 at temperatures even above 600° C. without deformations or breakages, differently from traditional conveyance systems with rollers.

Also, the flat surface prevents the deposited material from reaching and dirtying the side of the panel 5 which will be exposed to the sun, differently from traditional conveyors with rollers or with suspension from clamps, and allows to avoid a subsequent step of cleaning with dangerous substances.

Also, the flat surface allows to make the glass sheets 5 pass below the deposition stations 7 and 8 in an adjacent position, at a minimum distance from each other, so as to minimize turbulence, edge effects and consequent irregularities in the distribution of the film and waste of material.

In the embodiment with an inclined roller bed, the shape of the belt prevents lateral sliding of the glass panels 5.

The belt 22 is heated together with the glass sheet 5 with which it exchanges heat by conduction and thus ensures better uniformity of the temperature of the glass sheet during deposition.

The system 24 for transmitting motion to the belt 22 is arranged laterally, outside the heated area. The transmission system 24 can also be arranged outside the vacuum chamber by means of gaskets and seals or by magnetic members.

The region 25 inside the belt, free from mechanical parts, is occupied by the heaters 6, which bring to the appropriate temperature the segments 222 of the belt 22 and, by means of the segments 222, the side exposed the sun of the glass sheet 5.

The underlying region, where the belt 22 returns, can be used to clean the belt from residues of semiconductor by means of a cleaning means 26. The material is recovered and sent to regeneration.

The third section, constituted by rollers 23 having independent motion, like the first section, allows to accommodate the glass sheet 5 that exits from the belt 22 at a temperature below 600° C., and therefore without risk of deformations, move it at a higher speed, spacing it from the row of glass sheets on the belt, to the exit load lock 4.

In the exit load lock 4, the glass sheet 5 stops and, before returning to atmospheric pressure, is tensioned with jets of nitrogen from both sides.

The conveyance system with mechanical belt allows to arrange side by side in the same machine two parallel and independent lines, with the deposition stations facing outward, as shown schematically in FIG. 9.

The mechanical belt conveyance system, according to the present invention, has several advantages with respect to traditional systems with rollers or with suspended panels.

With the mechanical belt system, the glass sheet on the sun side is in fact masked and does not get dirty.

It is also possible to work at temperatures above 600° C. without risks of deformation and with lower risks of breakage.

Another advantage is constituted by the fact that in the deposition region a continuous plane, constituted by the queued glass sheets and by the lateral parts of the belt, is presented to the gas stream: it is believed that this reduces the edge effect caused by turbulence and provides a more uniform deposition.

FIGS. 10-16 show an apparatus according to a further aspect of the invention, which is generally designated by the reference numeral 101 and is provided with a conveyance system with trays.

The apparatus 101 comprises a vacuum chamber 102, an entry load lock 103 and an exit load lock 104.

The vacuum chamber 102 is provided with vacuum pumps capable of vacuum levels higher than 20 torr.

The entry load lock 103 has the minimum cross-section and volume indispensable to accommodate the glass sheet 5, so as to minimize the emptying time.

The exit load lock 104 accommodates a subsystem which provides surface tensioning of the glass sheet in nitrogen.

The orientation of the glass sheets through the apparatus can be horizontal or inclined.

The vacuum chamber has a conveyance system which is adapted to move the glass sheet from the entry load lock 103 to the chamber 102, inside the chamber 102, and from the chamber 102 to the exit load lock 104.

The vacuum chamber 102 comprises a series of electric heaters 106 for heating the glass sheet from ambient temperature to the semiconductor deposition temperature, comprised between approximately 550° C. and 680° C.

The vacuum chamber 102 has a first station 107 for deposition of the first semiconductor by evaporation or sublimation, a second station 108 for deposition of the second semiconductor by evaporation or sublimation, and a cooling station 109 provided by means of absorbers.

The heaters 106 are arranged on both faces of the glass sheet, parallel to it, and are controlled by means of independent control systems, which allow to manage the level of irradiation in a differentiated manner along the two dimensions of the glass sheet and on the two sides.

The absorbers are arranged on both faces of the glass sheet, parallel to it and are controlled by means of independent control systems, which allow to manage the level of irradiation in a differentiated manner along the two dimensions of the glass sheet and on the two sides.

The vacuum chamber is provided with ports which allow rapid replacement of all the elements: heaters, absorbers, deposition stations, components of the conveyance system.

The tray conveyance system comprises trays 122 made of an adequate material, for example graphite or ceramics.

Each tray 122 supports a glass panel 5 on its entire surface.

The trays 122 may be contoured to accommodate the entire thickness of the glass sheet in a preset position and prevent its sliding.

The contoured shape of the trays also reduces irregularities in the deposition of the thin film at the edges, by presenting a flat surface flush with the glass sheet.

Successive trays arrive at the deposition region in an adjacent position or at a distance of a few tenths of a millimeter. In this manner, the gas stream strikes a flat surface that is larger than the individual glass sheet and the edge effects are displaced outside of the glass sheet.

The trays 122 are conveyed by motorized belts 123, which allow the independent movement of two consecutive trays. In this manner each glass panel 5 can have a speed different from the others and can stop while the others remain in motion.

A possible embodiment is constituted by two different types of system of trays which alternate. A first type of tray has wide resting areas and is conveyed by a first pair of belts; a second type has narrow support areas and is conveyed by a second pair of belts.

In the embodiment with inclined glass sheet, shown in FIGS. 14-16, a series of idle rollers 125 supports the tray along the profile, preventing its sliding and ensuring its alignment.

The tray 122 receives the glass panel 5 in the loading region 111 with a robotized loading system or by sliding from a previous roller bed by means of adapted pushers.

The tray 122 then proceeds from the loading region 111 to the entry load lock 103, remains stationary in the entry load lock 103 for the required time and passes from the entry load lock 103 to the vacuum chamber 102.

The tray 122 continues through the first heaters at a higher speed than the preceding ones, reaches the tray that precedes it and queues behind it at a preset distance, which can also be nil.

The tray is heated together with the glass sheet up to the deposition temperature without the glass sheet undergoing deformations even in case of a temporary stop.

The tray then proceeds at the same speed as the trays that precede it in the final heating region and in the two deposition regions 107 and 108.

The tray is heated together with the glass sheet with which it exchanges heat by conduction, and thus ensures greater uniformity of the temperature of the glass sheet during deposition.

Once deposition has ended, the tray 122 proceeds at a higher speed, moving away from the preceding ones and moving into the exit load lock 104, where it stops, and before returning to atmospheric pressure the tensioning of the glass sheet with nitrogen jets from both sides occurs.

The nitrogen jets can reach the side to be exposed to the sun of the glass sheet in two ways: through adapted holes provided in each tray 122 and/or by moving the glass panel, from the tray to rollers by means of an adapted pusher.

At the exit from the load lock 104, the glass panel 5, if it has not already been unloaded for the tensioning step, is unloaded by an automatic system, for example by means of robots with sectors or by sliding by means of adapted pushers.

The trays 122 return to the initial portion of the apparatus, i.e., to the loading region 111, by means of a transit roller bed 127, a return belt 128 and a transit roller bed 126, to subsequently accommodate a new glass sheet 5.

The tray conveyance system allows to arrange two parallel and independent lines side by side in the same machine, with the deposition stations facing outwards.

The apparatus provided with a tray conveyance system can be provided with a cleaning means, not visible in the figures, which is arranged in the region of return of the trays and cleans the trays from the semiconductor residues. The material is recovered and sent to regeneration.

The tray conveyance system according to the present invention has several advantages with respect to traditional systems with rollers or with suspended panels.

In the tray system the glass sheet is masked on the sun side and does not get dirty and it is also possible to work at temperatures above 600° C. without risks of deformation and with reduced risks of breakage.

Another advantage resides in that a continuous plane, constituted by the queueing glass plates and by the lateral parts of the belt, is presented to the gas stream in the deposition region: it is believed that this reduces the edge effect caused by turbulence and improves the uniformity of the deposition.

FIGS. 17-24 illustrate an apparatus according to a further aspect of the invention, generally designated by the reference numeral 201, which is provided with a frame conveyance system.

The apparatus 201 comprises a vacuum chamber 202, an entry load lock 203 and an exit load lock 204.

The vacuum chamber 202 is provided with vacuum pumps capable of vacuum levels higher than 20 torr.

The entry load lock 203 has the minimum cross-section and volume indispensable to accommodate the glass sheet 5, so as to minimize emptying times.

The exit load lock 204 accommodates a subsystem that is adapted to provide the surface tensioning in nitrogen of the glass sheet.

The orientation of the glass sheets through the apparatus can be horizontal or inclined.

The vacuum chamber has a conveyance system which is adapted to move the glass sheet from the entry load lock 103 to the chamber 202, inside the chamber 202, and from the chamber 202 to the exit load lock 204.

The vacuum chamber 202 comprises a series of electric heaters for heating the glass sheet from ambient temperature to the semiconductor deposition temperature, which is comprised between approximately 550° C. and 680° C.

The vacuum chamber 202 has a first station 207 for deposition of the first semiconductor by evaporation or sublimation, a second station 208 for deposition of the second semiconductor by evaporation or sublimation, and a cooling station 209 provided with absorbers.

The heaters are arranged on both faces of the glass sheet, parallel to it, and are controlled by means of independent control systems which allow to manage the level of irradiation in a differentiated manner along the two dimensions of the glass sheet and on the two sides.

The absorbers are positioned on both faces of the glass sheet, parallel to it, and are controlled by means of independent control systems which allow to manage the level of irradiation in a differentiated manner along the two dimensions of the glass sheet and on the two sides.

The vacuum chamber 202 is provided with ports which allow rapid replacement of all the elements: heaters, absorbers, deposition stations, components of the conveyance system.

The tray conveyance system has a series of trays 230, each of which supports a glass panel 5 on the four edges for a few millimeters.

The frame may be provided with pantograph clamps which support the glass sheet 5 from above.

The frame 230 prevents a deformation of the glass sheet during temperature treatment and also has the function of masking the glass sheet in such a manner that only the side that must undergo deposition is exposed, so that the opposite side may not be soiled accidentally.

The frame 230 is conveyed in a subvertical position, for example with an inclination of approximately 7°, as shown schematically in FIGS. 22-24, and can support the glass sheet 5 with the face onto which deposition is to occur facing up (FIGS. 20 and 23) or down (FIGS. 21 and 22).

The deposition stations 207 and 208 are consequently on the right or left side of the apparatus.

If the face onto which deposition is to occur is arranged downward, the frame ensures a masking of a perimetric band of a few millimeters.

This allows to avoid the conventional step of cleaning the perimetric band by sanding or laser.

The frames 230 have an upper and lower band 231 in order to reduce the deposition irregularities of the thin film at the edges, constituting a flat surface together with the glass sheet.

Successive frames arrive in the deposition region in an adjacent position or at a distance of a few tenths of a millimeter. In this manner, the stream of gas strikes a flat surface that is larger than the individual glass sheet and the edge effects are displaced outside of the glass sheet.

The frames 230 are conveyed by motorized belts 223 which allow the independent movement of two consecutive frames. In this manner, each glass sheet may have a different speed from the others and can stop while the others remain in motion.

A possible embodiment is constituted by a system of frames of two different types which alternate.

A first type of frame has a traction wing which is extended in the upper right part and is conveyed by a first belt; the second type has a traction wing on the left and is conveyed by a second belt.

The frame 230 receives the glass sheet 5 in a loading region 211 with robotized loading; the frame 230 then proceeds from the loading region 211 to the entry load lock 203, stops in the entry load lock 23 for the required time and passes from the entry load lock 203 to the vacuum chamber 202.

The frame 230 then continues through the first heaters at higher speeds than the preceding ones and reaches the frame that precedes it and queues behind it at a preset distance, which may be nil.

The frame is then heated together with the glass sheet up to the deposition temperature without undergoing deformations of the glass sheet even in case of a temporary stop, and proceeds at the same speed as the frames that precede it in the final heating region and in the two deposition regions 207 and 208.

Once deposition has ended, the frame 230 proceeds at a higher speed, moving away from the preceding ones and moving into the exit load lock 204, where it stops, and before returning to atmospheric pressure, the glass sheet is tensioned with nitrogen jets on both sides.

At the exit from the load lock 204, the glass sheet 5 is unloaded by an automatic system.

The frames 230 return to the initial region of the apparatus with a return belt, which is not shown in the figures, in order to accommodate a new glass sheet.

The apparatus provided with the frame conveyance system may have a cleaning means, not visible in the figures, which is arranged in the return region of the frames and cleans the frames from the semiconductor residues. The material is recovered and sent to regeneration.

The frame conveyance system allows to arrange two parallel and independent lines side by side in the same machine, with the deposition stations facing outward.

The frame conveyance system, according to the present invention, has several advantages with respect to traditional systems with rollers or with suspended panels.

In the tray system, the glass sheet on the sun side is masked and does not get soiled and it is also possible to work at temperatures above 600° C., without risks of deformation and with reduced breakage risks.

Another advantage resides in that a continuous plane, constituted by the queueing glass sheets and by the lateral parts of the belt, is presented in front of the gas stream in the deposition region: it is believed that this reduces the edge effect caused by the turbulence and improves the uniformity of deposition.

In practice it has been found that the invention achieves the intended aim and objects, providing an apparatus for the deposition of thin films of two semiconductors on glass sheets, having various dimensions and a typically rectangular shape, for manufacturing photovoltaic panels, which is improved with respect to existing systems.

This application claims the priority of Italian Patent Application No. MI2010A000416, filed on Mar. 15, 2010, the subject matter of which is incorporated herein by reference.

1. An apparatus for the deposition of semiconductor material on a glass sheet, comprising at least one vacuum chamber which comprises a means for deposition of a semiconductor material on one or more glass sheets and a conveyance means for the conveyance of said glass sheets inside said vacuum chamber; wherein said conveyance means forms a continuous plane with the surface of each of said sheets that is subjected to the deposition of conducting material.

2. The apparatus according to claim 1, wherein said conveyance means comprises a mechanical belt constituted by individual segments arranged side by side, said segments each being contoured so as to accommodate the entire thickness of a respective one of said glass sheets and forming a continuous flat surface that is extended to the side of said respective one of said glass sheets.

3. The apparatus according to claim 1, wherein said conveyance means comprises a series of trays, each of said trays being adapted to support a glass sheet on its entire surface; each of said trays being contoured to accommodate the entire thickness of a respective one of said glass sheets in a specific position and prevent sliding of said respective one of said glass sheets and constituting, together with said respective one of said glass sheets, a continuous flat surface.

4. The apparatus according to claim 3, wherein said trays are conveyed by motorized belts so as to allow the independent movement of two consecutive trays and so that each of said glass sheets may have a different speed from the others of said glass sheets and can stop while the others remain in motion.

5. The apparatus according to claim 4, wherein said trays are of at least two different types; a first type of tray has wide resting members and is conveyed by a first pair of belts; and a second type of tray has narrow resting members and is conveyed by a second pair of belts.

6. The apparatus according to claim 3, wherein the trays are inclined; and said conveyance means comprise free rollers, which are adapted to support said trays along edges of said trays, preventing sliding and ensuring alignment of said trays.

7. The apparatus according to claim 1, wherein said conveyance means comprises a series of frames, each of said frames supporting a glass sheet on four edges of such sheet.

8. The apparatus according to claim 7, wherein said frames comprise pantograph clamps that support respective ones of said sheets from above.

9. The apparatus according to claim 7, wherein said frames each comprise a mask that covers a side of a respective one of said sheets that will not undergo the deposition of semiconductor material.

10. The apparatus according to claim 7, wherein said frames can support said glass sheets with sides thereof subjected to said deposition facing upward or downward.

11. The apparatus according to claim 1, further comprising an entry load lock, upstream of said vacuum chamber, and an exit load lock, downstream of said vacuum chamber; wherein said entry load lock has a minimum cross-section and volume, just enough to accommodate at least one glass sheet; and wherein said exit load lock accommodates a subsystem adapted to provide a nitrogen surface tensioning said glass sheet.

12. The apparatus according to claim 1 wherein said glass sheets are conveyed in a horizontal or inclined position.

13. The apparatus according to claim 11, wherein said conveyance means moves said glass sheets from said entry load lock to said vacuum chamber, said conveyance means moves said glass sheets inside said vacuum chamber, and said conveyance means moves said glass sheets from said vacuum chamber to said exit load lock.

14. The apparatus according to claim 1 wherein said vacuum chamber comprises electric heaters for heating the glass sheets from ambient temperature to a semiconductor deposition temperature, which is comprised between approximately 550° C. and 680° C.

15. The apparatus according to claim 14 wherein said vacuum chamber comprises a first station for the deposition of a first semiconductor by evaporation or sublimation and a second station for deposition of a second semiconductor by evaporation or sublimation, said vacuum chamber also comprising a cooling station provided with absorbers.

16. The apparatus according to claim 15 wherein said heaters are arranged on both faces of the glass sheets, parallel to said faces, and are controlled by means of independent control systems that allow management of the level of irradiation in a differentiated manner along the two dimensions of the glass sheets and on the two sides thereof; and wherein said absorbers are arranged on both of said faces of the glass sheets, parallel to said faces, and are controlled by means of independent control systems that allow management of the level of irradiation in a differentiated manner along the two dimensions of the glass sheets and on the two sides thereof.

17. The apparatus according to claim 15 wherein said vacuum chamber is provided with ports which allow rapid replacement of all the internal components: said heaters, said absorbers, said deposition stations and the components of said conveyance means.

18. The apparatus according to claim 1, further comprising a cleaning means, which is arranged in the region that lies below the return of said conveyance means and is adapted to clean said conveyance means from residues of semiconductor; the material removed by said cleaning means is recovered and sent to regeneration.
